(19) United States
(12) Patent Application Publication
(10) Pub. No.: US 2023/0290661 A1
(43) Pub. Date: Sep. 14, 2023

(54) SINGULATED DIE SHIPPING TRAY ASSEMBLY

(71) Applicant: Intel Corporation, Santa Clara, CA (US)

(72) Inventors: Kyle ARRINGTON, Gilbert, AZ (US); Kirk WHEELER, Chandler, AZ (US); Emily SCHUBERT, Portland, OR (US); Dingying XU, Chandler, AZ (US); Bassam ZIADEH, Gilbert, AZ (US)

(21) Appl. No.: 17/692,247

(22) Filed: Mar. 11, 2022

(51) Int. Cl. H01L 21/673

(52) U.S. Cl. CPC H01L 21/67336; H01L 21/67356; H01L 21/67366; H01L 21/67369; H01L 21/67386; H01L 21/67396

(57) ABSTRACT

The present disclosure relates to a tray assembly. The tray assembly may include a die transport tray. The die transport tray may include an inner bottom surface for accommodating a plurality of dies. The tray assembly may further include a lid. The lid may include an inner top surface, wherein the inner top surface of the lid may face the inner bottom surface of the die transport tray when the lid is assembled over the die transport tray. The lid may further include a shock absorbing material on the inner top surface for contacting the plurality of dies, if present.

### BACKGROUND

Semiconductor die shipping is currently performed by a tape and reel technology. Semiconductor dies (or simply, dies) are placed into a pocket of a thermoformed reel and then sealed with a thermal adhesive. This method has proven to work with traditional dies; however, this method is limited to the size or form-factor of the dies to be shipped. As the die or die complex becomes larger, the reel has to grow in order to accommodate the die size to safely transport the die. Extra-large die complexes cannot be shipped in tape and reel due to the curvature required for the reel. This eventually hits a maximum size requirement for the reel to be able to prevent damage caused to the dies, for example, during shipping of the dies.

Current die shipping trays that are utilized in high volume manufacturing cannot be used to ship die in its current configuration. For the current trays, a textured thermoplastic elastomer (TPE) is utilized to hold the die in place during singulated die testing. This textured surface is designed to allow for enough “tack” to hold the die in place during the testing but must easily allow for the dies to be picked up under a low force. However, this optimized tack can be readily overcome by a shock and vibe event that may occur during shipping. FIG. 1 shows dies movement in a conventional tray after experiencing a shock event.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows die movement in a prior art shipping tray after a shock event;

FIGS. 2A and 2B show a pocketless tray assembly (top view and cross-sectional view, respectively) for die shipping according to one aspect of the present disclosure;

FIG. 3A shows a spring option as a shock absorbing layer according to one aspect of the present disclosure;

FIG. 3B shows a soft polymer as a shock absorbing layer according to another aspect of the present disclosure;

FIG. 4A shows a photo of a shipping tray with a foam insert in a lid;

FIG. 4B shows the results of a shock and vibe experiment carried out on the shipping tray of FIG. 4A;

FIG. 5 shows a flow chart illustrating a method for packing a plurality of dies in a tray assembly according to an aspect of the present disclosure.

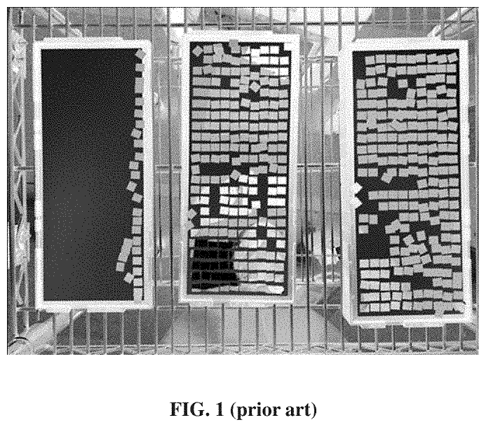

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for systems, and various aspects are provided for methods. It will be understood that the basic properties of the systems also hold for the methods and vice versa. Other aspects may be utilized and structural, and logical changes may be made without departing from the scope of the present disclosure. The various aspects are not necessarily mutually exclusive, as some aspects may be combined with one or more other aspects to form new aspects.

As used herein, the singular forms “a”, “an” and “the” include support for plural referents unless the context clearly dictates otherwise.

The terms “front”, “rear”, “top”, “bottom”, and the like used herein and in the claims are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

The present disclosure generally relates to a tray assembly. The tray assembly may include a die transport tray including an inner bottom surface for accommodating a plurality of dies. The tray assembly may further include a lid including an inner top surface, wherein the inner top surface of the lid may face the inner bottom surface of the die transport tray when the lid may be assembled over the die transport tray. The lid may further include a shock absorbing material on the inner top surface for contacting the plurality of dies, if present.

The present disclosure generally further relates to a lid. The lid may be configured to assemble with a die transport tray for shipping a plurality of dies. The lid may include an inner top surface and may further include a shock absorbing material on the inner top surface for contacting the plurality of dies, if present.

The present disclosure generally further relates to a method. The method may include providing a die transport tray including an inner bottom surface. The method may further include placing a plurality of dies on the inner bottom surface of the die transport tray. The method may include providing a lid including an inner top surface, wherein the lid may further include a shock absorbing material on the inner top surface for contacting the plurality of dies. The method may also include assembling the lid over the die transport tray such that the inner top surface may face the inner bottom surface.

Various aspects of the present disclosure may be directed to various designs or configurations of a lid for a tray assembly. The tray assembly may be for shipping singulated dies. In a convention tray, there are a plurality of compartments or pockets to accommodate a plurality of dies therein. On the other hand, the presently disclosed die transport tray (also interchangeably called die shipping tray or simply, tray) does not contain such compartments, i.e., the die transport tray may be pocketless. The pocketless die transport tray may allow for shipping of a die regardless of its form factor and size. Advantageously, a tacky surface may be provided in the die transport tray that may allow for the dies to be readily picked and placed onto and off the die transport tray. More advantageously, a lid with a leaf spring-like material may provide a constant downward pressure onto the dies to prevent the dies from moving during shipping.

To more readily understand and put into practical effect the present disclosure, particular aspects will now be described by way of examples and not limitations, and with reference to the drawings. For the sake of brevity, duplicate descriptions of features and properties may be omitted.

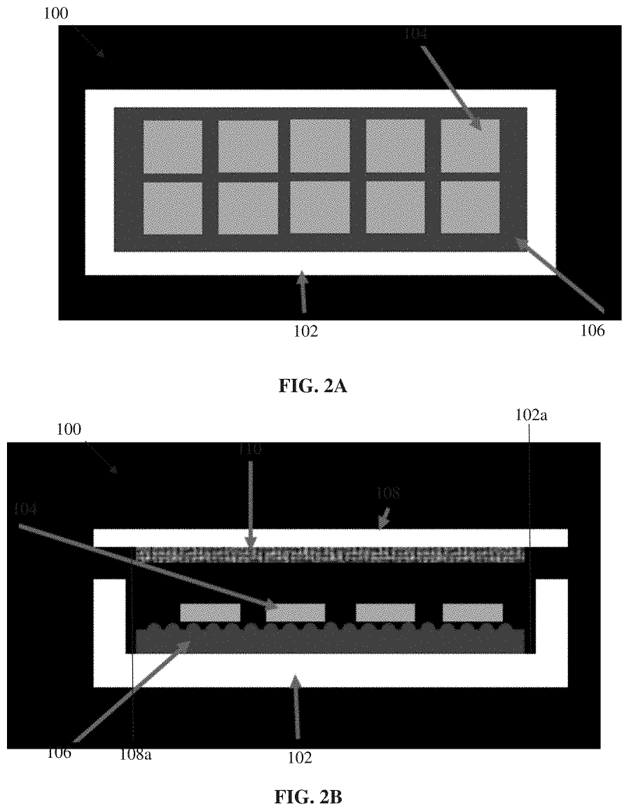

FIG. 2A shows top view of a pocketless tray assembly 200 for die shipping according to one aspect. FIG. 2B shows a cross-sectional view of the pocketless tray assembly 200 of FIG. 2A.

The tray assembly 200 may have dimensions conforming to the Joint Electron Device Engineering Council (JEDEC) standards.

The tray assembly 200 may include a die transport tray 202. The die transport tray 202 may include an inner bottom surface 202a for accommodating a plurality of dies 204. In other words, the plurality of dies 204 may be placed on the inner bottom surface 202a of the die transport tray 202.

The plurality of dies 204 may be any semiconductor or integrated circuit dies. The plurality of dies 204 may include any form factor or size.

In one aspect, a tacky surface 206 (or adhesive surface) may be formed on the inner bottom surface 202a prior to placing the plurality of dies 204 thereon. The tacky surface 206 may create a sticky surface to allow for the plurality of dies 204 to be readily picked up and placed onto and off the die transport tray 202. The tacky surface 206 may be formed on the inner bottom surface 202a by conventional methods such as injection molding or lamination. The tacky surface 206 may be a flat, roughened, or patterned surface to keep the dies 204 in place. With the provision of the tacky surface 206 in the die transport tray 202, the dies 204 may be isolated from one another without having a need for inner walls in the die transport tray 202 (i.e., pocketless) to physically separate the dies 204. The tackiness of the tacky surface 206 may restrict lateral movement of the dies 204 such that the dies 204 do not contact one another even during shipping or shock.

In one aspect, the tacky surface 206 may include a thermoplastic elastomer (TPE), natural rubber, nitrile rubber, soft silicones, and soft polyurethanes.

The tray assembly 200 may further include a lid 208. The lid 208 may include an inner top surface 208a. The inner top surface 208a may face the inner bottom surface 202a of the die transport tray 202 during assembly of the lid 208 over the tray 202 as shown in FIG. 2B. The lid 208 may further include a shock absorbing material 210 on the inner top surface 208a for contacting the plurality of dies 204.

The shock absorbing material 210 may include a leaf spring like material that may conform to the dies 204 and exert a constant downward pressure onto the dies 204 that may prevent the dies 204 from moving during shipping or shock. By exerting a compressive downward force onto the dies 204, the shock absorbing material 210 further secures the dies 204 in place. This combination of the high shear and peak tack forces from the pocketless die transport tray 202 with the compressive force from the lid 208 may allow for a secure media that may prevent die movement during shipping.

The shock absorbing material 210 may include a foam, such as an open cell foam or a closed cell foam. Conventional methods may be employed to attach the foam to the lid 208. For example, the foam may be laminated, dispensed, or sprayed onto the lid 208. A laminated foam may utilize a pressure sensitive adhesive or a structural adhesive to attach the foam to the lid 208 by a roller mechanism. A dispensed or sprayed foam may be applied directly onto the lid 208. The foam should be highly compressible, allowing for thick or thin die/die complexes. At the same time, the foam should also be sufficiently stiff and must not stress relax over time to provide constant pressure on the dies 204 to prevent the dies 204 from moving.

Additional shock absorbing materials 210 that could be attached to the lid 208 may include springs (polymeric or metallic), fine mesh grids, and soft polymer (modulus <1 mPa). These materials may be laminated, or dual shot injection molded onto the lid 208, resulting in a feature that may apply a load onto the dies 204 on the die transport tray 202.

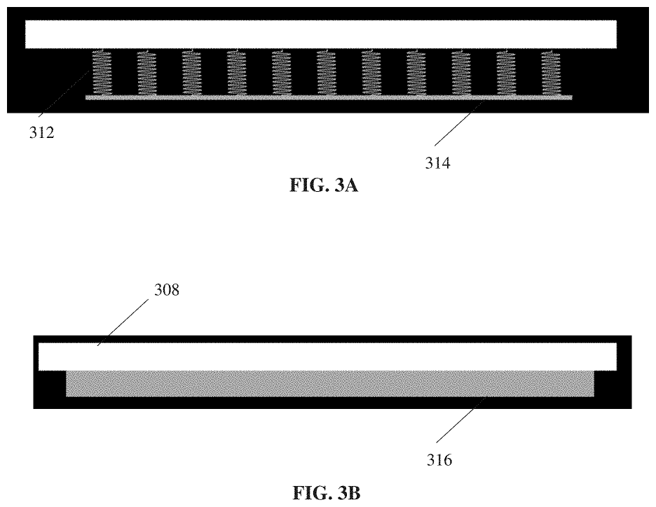

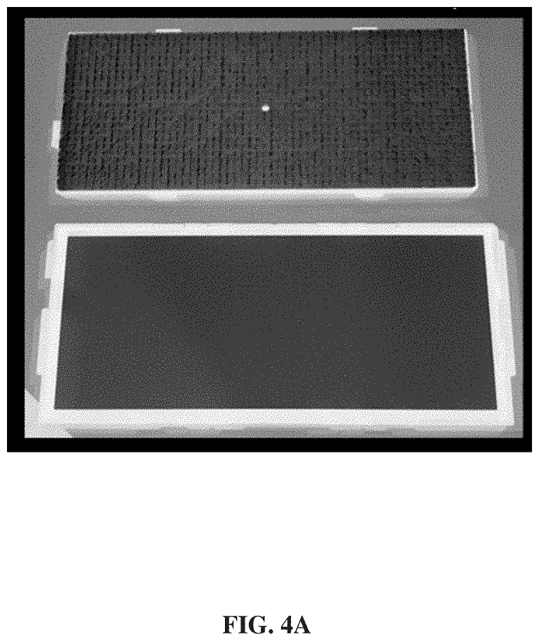

FIG. 3A shows a spring option that may either have the springs 312 directly touching the dies, or an electrostatic dissipative (ESD) thin film 314 attached to the springs 312, allowing for the constant tension.

FIG. 3B shows a soft polymer 316 attached to a lid 308. Soft polymers, such as silicones, natural rubbers, thermoplastic elastomers, and polyurethanes, may be laminated, or injection molded onto the lid 308. These very soft polymers 316 may deform around the dies in order to keep them in place.

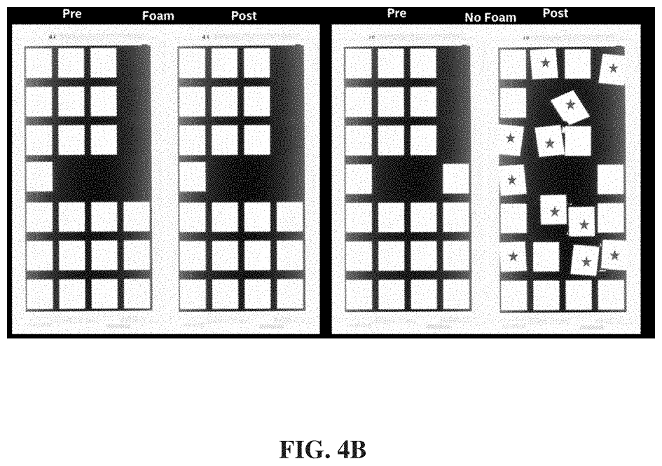

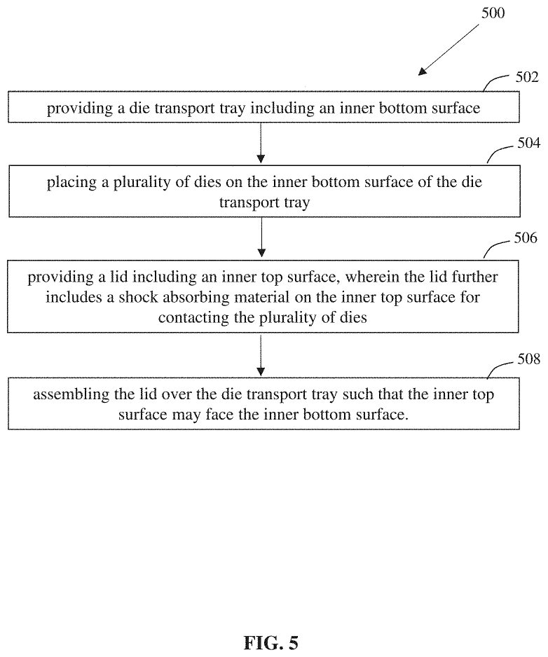

FIG. 4A shows a photo of a shipping tray with a foam insert in a lid; FIG. 4B shows the results of a shock and vibe experiment carried out on the shipping tray of FIG. 4A.

A proof-of-concept experiment was performed by adding in a freestanding foam on top of dies on a shipping tray with a conventional lid (see FIG. 4A). In other words, the foam is not attached to the lid.

Trays with the foam insert and without the foam insert were placed through a shock and vibe test. After the test, the trays with the foam insert showed no die movement, while the trays without the foam insert either moved or cracked (see FIG. 4B). These results prove that the foam insert may provide a constant downward pressure onto the dies to prevent the dies from moving during shock. However, the use of freestanding foam inserts may not be suitable for high volume manufacturing since the freestanding foam inserts would have to be manually placed and removed after shipping, which would impact run rates and require more manual processing which could impact the dies as a human could bump a die while placing or removing the foam inserts. Therefore, by attaching foam inserts, or other shock absorbing materials, to a tray lid, run rates may be improved, and less manual processing may be needed, rendering the presently disclosed tray assembly suitable for high volume manufacturing.

FIG. 5 shows a flow chart illustrating a method for packing a plurality of dies in a tray assembly according to an aspect of the present disclosure.

At operation 502, the method 500 may include providing a die transport tray including an inner bottom surface.

At operation 504, the method 500 may include placing a plurality of dies on the inner bottom surface of the die transport tray.

At operation 506, the method 500 may include providing a lid including an inner top surface, wherein the lid may further include a shock absorbing material on the inner top surface for contacting the plurality of dies.

At operation 508, the method 500 may include assembling the lid over the die transport tray such that the inner top surface may face the inner bottom surface.

It will be understood that the above operations described above relating to FIG. 5 are not limited to this particular order. Any suitable, modified order of operations may be used.

### Examples

Example 1 may include a tray assembly including a die transport tray including an inner bottom surface for accommodating a plurality of dies, and a lid including an inner top surface, wherein the inner top surface of the lid may face the inner bottom surface of the die transport tray when the lid is assembled over the die transport tray, wherein the lid may further include a shock absorbing material on the inner top surface for contacting the plurality of dies, if present.

Example 2 may include the tray assembly of example 1 and/or any other example disclosed herein, wherein the shock absorbing material may include a foam, a spring, a fine mesh grid, or a soft polymer.

Example 3 may include the tray assembly of example 2 and/or any other example disclosed herein, wherein the foam may include an open cell foam.

Example 4 may include the tray assembly of example 2 and/or any other example disclosed herein, wherein the foam may include a closed cell foam.

Example 5 may include the tray assembly of example 2 and/or any other example disclosed herein, wherein the spring may include a polymeric spring or a metallic spring.

Example 6 may include the tray assembly of example 5 and/or any other example disclosed herein, wherein the lid may further include an electrostatic dissipative layer attached to the spring.

Example 7 may include the tray assembly of example 2 and/or any other example disclosed herein, wherein the soft polymer may include a modulus of less than 1 mPa.

Example 8 may include the tray assembly of example 7 and/or any other example disclosed herein, wherein the soft polymer may include a silicone, a natural rubber, a thermoplastic elastomer, or a polyurethane.

Example 9 may include the tray assembly of example 1 and/or any other example disclosed herein, wherein the inner bottom surface may include an adhesive surface.

Example 10 may include a lid and/or any other example disclosed herein, the lid being configured to assemble with a die transport tray for shipping a plurality of dies, the lid including an inner top surface and further including a shock absorbing material on the inner top surface for contacting the plurality of dies, if present.

Example 11 may include the lid of example 10 and/or any other example disclosed herein, wherein the shock absorbing material may include a foam, a spring, a fine mesh grid, or a soft polymer.

Example 12 may include the lid of example 11 and/or any other example disclosed herein, wherein the foam may include an open cell foam.

Example 13 may include the lid of example 11 and/or any other example disclosed herein, wherein the foam may include a closed cell foam.

Example 14 may include the lid of example 11 and/or any other example disclosed herein, wherein the spring may include a polymeric spring or a metallic spring.

Example 15 may include the lid of example 10 and/or any other example disclosed herein, wherein the lid may further include an electrostatic dissipative layer attached to the spring.

Example 16 may include the lid of example 11 and/or any other example disclosed herein, wherein the soft polymer may include a modulus of less than 1 mPa.

Example 17 may include the lid of example 16 and/or any other example disclosed herein, wherein the soft polymer may include a silicone, a natural rubber, a thermoplastic elastomer, or a polyurethane.

Example 18 may include a method and/or any other example disclosed herein, the method may include providing a die transport tray including an inner bottom surface; placing a plurality of dies on the inner bottom surface of the die transport tray; providing a lid including an inner top surface, wherein the lid may further include a shock absorbing material on the inner top surface for contacting the plurality of dies; and assembling the lid over the die transport tray such that the inner top surface may face the inner bottom surface.

Example 19 may include a method of example 18 and/or any other example disclosed herein, wherein the shock absorbing material may include a foam, a spring, a fine mesh grid, or a soft polymer.

Example 20 may include a method of example 18 and/or any other example disclosed herein, wherein the inner bottom surface may include an adhesive surface.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

While the present disclosure has been particularly shown and described with reference to specific aspects, it should be understood by persons skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A tray assembly comprising:
a die transport tray comprising an inner bottom surface for accommodating a plurality of dies; and
a lid comprising an inner top surface, wherein the inner top surface of the lid faces the inner bottom surface of the die transport tray when the lid is assembled over the die transport tray,
wherein the lid further comprises a shock absorbing material on the inner top surface for contacting the plurality of dies, if present.

2. The tray assembly of claim 1, wherein the shock absorbing material comprises a foam, a spring, a fine mesh grid, or a soft polymer.

3. The tray assembly of claim 2, wherein the foam comprises an open cell foam.

4. The tray assembly of claim 2, wherein the foam comprises a closed cell foam.

5. The tray assembly of claim 2, wherein the spring comprises a polymeric spring or a metallic spring.

6. The tray assembly of claim 5, wherein the lid further comprises an electrostatic dissipative layer attached to the spring.

7. The tray assembly of claim 2, wherein the soft polymer has a modulus of less than 1 mPa.

8. The tray assembly of claim 7, wherein the soft polymer comprises a silicone, a natural rubber, a thermoplastic elastomer, or a polyurethane.

9. The tray assembly of claim 1, wherein the inner bottom surface comprises an adhesive surface.

10. A lid configured to assemble with a die transport tray for shipping a plurality of dies, the lid comprising an inner top surface and further comprising a shock absorbing material on the inner top surface for contacting the plurality of dies, if present.

11. The lid of claim 10, wherein the shock absorbing material comprises a foam, a spring, a fine mesh grid, or a soft polymer.

12. The lid of claim 11, wherein the foam comprises an open cell foam.

13. The lid of claim 11, wherein the foam comprises a closed cell foam.

14. The lid of claim 11, wherein the spring comprises a polymeric spring or a metallic spring.

15. The lid of claim 14, wherein the lid further comprises an electrostatic dissipative layer attached to the spring.

16. The lid of claim 11, wherein the soft polymer has a modulus of less than 1 mPa.

17. The lid of claim 16, wherein the soft polymer comprises a silicone, a natural rubber, a thermoplastic elastomer, or a polyurethane.

18. A method comprising:
providing a die transport tray comprising an inner bottom surface;
placing a plurality of dies on the inner bottom surface of the die transport tray;
providing a lid comprising an inner top surface, wherein the lid further comprises a shock absorbing material on the inner top surface for contacting the plurality of dies; and
assembling the lid over the die transport tray such that the inner top surface faces the inner bottom surface.

19. The method of claim 18, wherein the shock absorbing material comprises a foam, a spring, a fine mesh grid, or a soft polymer.

20. The method of claim 18, wherein the inner bottom surface comprises an adhesive surface.
